(19) United States
(12) Patent Application Publication
(10) Pub. No.: US 2025/0357256 A1
(43) Pub. Date: Nov. 20, 2025

(54) THERMAL CONDUCTIVE BONDING STRUCTURE

(71) Applicant: Taiwan Semiconductor Manufacturing Company, Ltd., Hsin-Chu (TW)

(72) Inventors: Yung-Ta Chen, Taichung City (TW); Kuan-Kan Hu, Hsinchu (TW); Chun-Yu Liu, New Taipei City (TW); Che Chi Shih, Taoyuan City (TW); Ku-Feng Yang, Hsinchu County (TW); Szuya Liao, Hsinchu (TW)

(21) Appl. No.: 19/283,677

(22) Filed: Jul. 29, 2025

Related U.S. Application Data
(63) Continuation-in-part of application No. 18/602,163, filed on Mar. 12, 2024.
(60) Provisional application No. 63/589,046, filed on Oct. 10, 2023.

(51) Int. Cl. H01L 23/373; H01L 23/00

(52) U.S. Cl. CPC H01L 23/3738; H01L 24/32; H01L 2224/32225

(57) ABSTRACT

A semiconductor device includes a semiconductor device layer having transistors, a frontside interconnect structure disposed over the semiconductor device layer and electrically coupled to the transistors, a backside interconnect structure disposed under the semiconductor device layer and electrically coupled to the transistors, a bonding structure disposed over the frontside interconnect structure, and a carrier substrate disposed over the bonding structure. The bonding structure includes thermal pillars embedded in a substrate, top surfaces of the thermal pillars interface with the carrier substrate, and bottom surfaces of the thermal pillars interface with the frontside interconnect structure.

### PRIORITY

This is a continuation application of U.S. patent application Ser. No. 18/602,163, filed Mar. 12, 2024, which claims benefit of U.S. Provisional Patent Application No. 63/589,046, filed Oct. 10, 2023, each of which is incorporated herein by reference in its entirety.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. Shrinking sizes and high integration density of semiconductor devices make the heat dissipation challenging. For example, as frontside and backside interconnect structures become more compact with ever-shrinking IC feature size, heat generated in the device layer of an IC may be trapped by the dielectric layers of the interconnect structures, which generally have poor thermal conductivity, and cause sharp local temperature peaks, sometimes referred to as thermal hotspots. Thermal hotspots due to heat generated by devices may negatively affect the electrical performance of the IC and often lead to electromigration and reliability issues for electronic components in the IC. Accordingly, although existing semiconductor structures have been generally adequate for their intended purposes, they have not been entirely satisfactory in all respects. Therefore, there is a need to solve or mitigate the above deficiencies and problems.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a cross-sectional view of layers involved in a semiconductor device, in accordance with some embodiments of the present disclosure.

FIGS. 2A, 2B, 2C, and 2D illustrate top views of thermal vias in a bonding structure, in accordance with some embodiments of the present disclosure.

FIG. 3 illustrates a cross-sectional view of a region of the semiconductor device of FIG. 1, in accordance with some embodiments of the present disclosure.

FIGS. 4A, 4B, 4C, 4D, 4E, 4F, 4G, 4H, 4I, and 4J-1 illustrate cross-sectional views of the semiconductor device of FIG. 1 during the formation of different layers, in accordance with some embodiments of the present disclosure.

FIGS. 4J-2, 4J-3, and 4J-4 illustrate cross-sectional views of the semiconductor device of FIG. 1, in accordance with some alternative embodiments of the present disclosure.

FIGS. 5A, 5B, 5C, and 5D-1 illustrate cross-sectional views of the semiconductor device of FIG. 1 during the formation of different layers, in accordance with some alternative embodiments of the present disclosure.

FIGS. 5D-2, 5D-3, and 5D-4 illustrate cross-sectional views of the semiconductor device of FIG. 1, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

Thermal energy in the form of heat may be generated during the operations of the electrical circuitries, and some types of electrical circuitries may generate more heat than other types of electrical circuitries. When the heat-generating electrical circuitries are closely packed together in an IC structure, one or more thermal hotspot regions may be formed. These thermal hotspot regions may refer to regions or areas on an IC structure where more heat is generated per unit area/volume per unit time than other regions of the IC structure. For example, a thermal hotspot region may have a greater temperature than a region that neighbors the thermal hotspot region during the operation of the IC structure.

Conventionally, semiconductor devices are built in a stacked-up fashion, having transistors at the lowest level (a semiconductor device layer) and a frontside interconnect structure (contacts, vias, and metal lines) on top of the transistors to provide connectivity to the transistors. Power rails (such as metal lines for voltage sources and ground planes) are also above the transistors and may be part of the interconnect structures. As the integrated circuits continue to scale down, so do the power rails. This inevitably leads to increased voltage drop across the power rails, as well as increased power consumption of the integrated circuits. Other than power rails, signal lines also suffer from such scaling down, such as the ever-reduced signal line pitches that leads to increased parasitic capacitance and reduced circuit speed. To address this challenge, a backside interconnect structure including power rails and/or signal lines, and vias formed on the backside of an IC structure, may be implemented to alleviate some metal routing burden from the frontside interconnect structure and reduce resistance and parasitic capacitance thereof. To access the backside of the IC structure, the IC structure is generally bonded to a carrier substrate (e.g., a wafer) through a dielectric bonding layer. However, the dielectric bonding layer generally has poor thermal conductivity and blocks the thermal dissipation path from the frontside of the IC structure. Meanwhile, the backside interconnect structure generally uses a low-k or extreme low-k (ELK) dielectric materials, which may also possess poor thermal conductivity. As a result, the dielectric bonding layer on the frontside of the IC structure, combined with the backside interconnect structure, can collectively deteriorate the thermal performance of the IC structure.

The present disclosure is generally related to a bonding structure that provides thermal conductive vias (also termed as thermal vias, thermal conductive pillars, or thermal pillars). The thermal vias are embedded in the bonding structure for improving an overall thermal conductivity of the bonding structure, allowing a quick dissipation of heat from thermal hotspot regions into a carrier substrate.

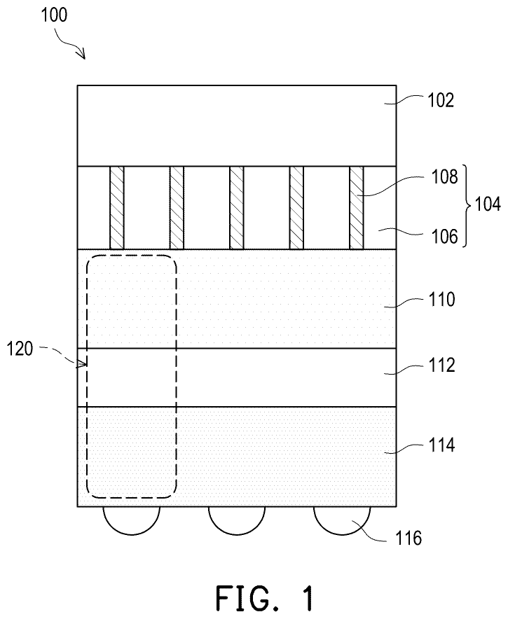

FIG. 1 is a cross-sectional diagram illustrating a semiconductor device 100, in accordance with some embodiments of the present disclosure. The semiconductor device 100 may be any semiconductor device, such as, but not limited to, a logic device, a memory device, or any other semiconductor device. In some embodiments, the semiconductor device 100 may be a semiconductor device package. In the illustrated embodiment, the semiconductor device 100 includes a carrier substrate 102, a bonding structure 104 that includes a dielectric layer 106 and an array of thermal vias 108, a frontside interconnect structure 110, a backside interconnect structure 114, and a semiconductor device layer 112 sandwiched between the frontside interconnect structure 110 and the backside interconnect structure 114.

The carrier substrate 102 may be any suitable substrate. In some embodiments, the carrier substrate 102 may be a semiconductor wafer. In some embodiments, the carrier substrate 102 may be a monocrystalline silicon (Si) wafer, an amorphous Si wafer, a gallium arsenide (GaAs) wafer, or any other semiconductor wafer. In some embodiments, the carrier substrate 102 may be a carrier wafer, which may be substantially free of electrical features and may be utilized to bond to the semiconductor device 100 (e.g., bonded to the frontside interconnect structure 110 and semiconductor device layer 112) during backside processing of the semiconductor device 100.

The semiconductor device layer 112 includes one or more semiconductor devices. The semiconductor devices included within the semiconductor device layer 112 may be any semiconductor devices in various embodiments. In some embodiments, the semiconductor device layer 112 includes one or more transistors, which may include any suitable transistor structures, including, for example, FinFET, gate-all-around (GAA) transistors, or the like. In some embodiments, the semiconductor device layer 112 includes one or more GAA transistors. In some embodiments, the semiconductor device layer 112 may be a logic layer that includes one or more semiconductor devices, and may further include their interconnection structures, that are configured and arranged to provide a logical function, such as AND, OR, XOR, XNOR, or NOT, or a storage function, such as a flipflop or a latch.

In some embodiments, the semiconductor device layer 112 may include a memory device, which may be any suitable memory device, such as, for example, a static random access memory (SRAM) device. The memory device may include a plurality of memory cells that are constructed in rows and columns, although other embodiments are not limited to this arrangement. Each memory cell may include multiple transistors (e.g., six) connected between a first voltage source (e.g., VDD) and a second voltage source (e.g., VSS or ground) such that one of two storage nodes can be occupied by the information to be stored, with the complementary information stored at the other storage node.

The semiconductor device layer 112 of the semiconductor device 100 may further include various circuitry that is electrically coupled to the semiconductor device layer 112. For example, the semiconductor device layer 112 may include power management or other circuitry that is electrically coupled to the one or more semiconductor devices of the semiconductor device layer 112. The power management circuitry may include any suitable circuitry for controlling or otherwise managing communication signals, such as input power signals, to or from the semiconductor devices of the semiconductor device layer 112. In some embodiments, the power management circuitry may include power-gating circuitry which may reduce power consumption, for example, by shutting off the current to blocks of the circuit (e.g., blocks or electrical features in the semiconductor device layer 112) that are not in use, thereby reducing stand-by or leakage power. In some embodiments, the semiconductor device layer 112 includes one or more switching devices, such as a plurality of transistors, that are used to transmit or receive electrical signals to and from the semiconductor devices in the semiconductor device layer 112, such as to turn on and turn off the circuitry (e.g., transistors, etc.) of the semiconductor device layer 112.

The frontside interconnect structure 110 is disposed at a frontside of the semiconductor device layer 112, e.g., at the upper side as shown in FIG. 1. IC manufacturing process flow is typically divided into three categories: front-end-of-line (FEOL), middle-end-of-line (MEOL), and back-end-of-line (BEOL). FEOL generally encompasses processes related to fabricating IC devices, such as transistors. For example, FEOL processes can include forming isolation features, gate structures, and source and drain features (generally referred to as source/drain features). MEOL generally encompasses processes related to fabricating contacts to conductive features (or conductive regions) of the IC devices, such as contacts to the gate structures and/or the source/drain features. BEOL generally encompasses processes related to fabricating a multilayer interconnect structure that interconnects IC features fabricated by FEOL and MEOL, thereby enabling operation of the IC devices. The frontside interconnect structure 110 may be referred to as a BEOL structure 110. In some embodiments, the frontside interconnect structure 110 has an overall thickness (e.g., between the semiconductor device layer 112 and the bonding structure 104) that is less than 10 μm. In some embodiments, the frontside interconnect structure 110 has an overall thickness that is less than 5 μm, and in some embodiments, is within a range from 0.1 μm to 5 μm. The frontside interconnect structure 110 may each include a dielectric layer having metallization features (e.g., vias, wires, traces or the like) embedded therein. The dielectric layers may be low-k dielectric layers, such as SiO₂, SION, SiOC, SiOCN, or the like. The metallization features may be or include copper, tungsten, ruthenium, molybdenum, titanium, titanium nitride, other metals, alloys thereof, multilayer combinations thereof, or the like.

The backside interconnect structure 114 is disposed at a backside of the semiconductor device layer 112, e.g., at the lower side as shown in FIG. 1. The backside interconnect structure 114 may include any suitable electrical interconnection structures, circuitry, wiring, or the like suitable to receive or transmit electrical signals to and from the semiconductor device layer 112. In some embodiments, the backside interconnect structure 114 includes a backside power rail. The backside power rail may be disposed, for example, between a backside power delivery network and backside vias which may electrically couple the backside power rail to the semiconductor devices in the semiconductor device layer 112. In some embodiments, the backside power rail of the backside interconnect structure 114 may include a plurality of conductive lines or power rails which operably deliver or receive electrical signals (e.g., power or voltage signals) to or from the semiconductor devices in the semiconductor device layer 112. The backside power rail may be formed of any suitable metallization features. The metallization features may be or include copper, tungsten, ruthenium, molybdenum, titanium, titanium nitride, other metals, alloys thereof, multilayer combinations thereof, or the like.

The backside interconnect structure 114 may further include an insulation layer covering the various features, e.g., conductive features, of the backside interconnect structure 114. For example, an insulation layer may be included which covers or substantially covers the backside power rail, the backside vias, and the metallization layers of the backside interconnect structure 114. The insulation layer may be formed of any suitable insulation material, and in some embodiments, the insulation layer electrically insulates or isolates the various electrical features within the backside interconnect structure 114 from one another. In some embodiments, the insulation layer may be formed of a dielectric material, which may include one or more of SiO₂, SION, SiOC and SiOCN or any other suitable insulating material. The insulation layer may be disposed on and in contact with the semiconductor device layer 112. In some embodiments, the backside interconnect structure 114 has a thickness that is less than 10 μm. In some embodiments, the backside interconnect structure 114 has a thickness that is less than 5 μm, and in some embodiments, is within a range from 0.1 μm to 5 μm.

In some embodiments, the semiconductor device 100 includes electrical contacts 116 electrically coupled to the metallization layers in the backside interconnection structure 114. The metallization layers extend between the electrical contacts 116 at the backside of the semiconductor device 100 and the semiconductor device layer 112. In some embodiments, the metallization layers electrically connect the electrical contacts 116 to one or more semiconductor devices in the semiconductor device layer 112. The metallization layers may be electrically coupled to one another through one or more conductive vias. In some embodiments, the electrical contacts 116 may be solder bumps, C4 (controlled-collapse chip connection) bumps, or the like.

The bonding structure 104 bonds the carrier substrate 102 to the frontside interconnect structure 110. The bonding structure 104 may also be referred to as the bonding layer 104. The bonding structure 104 may be formed of any material to suitably bond the carrier substrate 102 and the frontside interconnect structure 110. The bonding structure 104 includes a dielectric layer 106 and an array of thermal vias 108.

In some embodiments, the dielectric layer 106 is made of silicon oxide, silicon nitride, silicon carbide, low-k dielectrics such as carbon doped oxides, a low-k dielectric or an extreme low-k (ELK) dielectric such as porous carbon doped silicon dioxide, a polymer, such as an epoxy, polyimide, benzocyclobutene (BCB), polybenzoxazole (PBO), the like, or a combination thereof. In furtherance of some embodiments, the dielectric materials in the dielectric layer 106 and the dielectric layer(s) in the frontside interconnect structure 110 are different. For example, the dielectric layer(s) in the frontside interconnect structure 110 may have a dielectric constant less than that of the dielectric layer 106. In some embodiments, the dielectric layer 106 has an overall thickness between about 1 μm and about 10 μm.

The thermal vias 108 extend from the frontside interconnect structure 110 to the carrier substrate 102. The thermal vias 108 provide thermal conductive paths through the dielectric layer 106. In this manner, heat generated by the thermal hotspot region underneath can be quickly transferred to the thermal vias 108 and subsequently to the carrier substrate 102. In one embodiment, the carrier substrate 102 is made of monocrystalline silicon (Si) that exhibits a thermal conductivity around 148 W/m·K, which is capable of quickly and efficiently dissipating the heat generated by the thermal hotspot regions in the semiconductor device layer 112. As a result, the device performance, reliability, and/or the lifespan of the IC structure can be improved.

The thermal vias 108 are made of high-kappa material. In the context of the present disclosure, the term “high-kappa material” refers to a material with a thermal conductivity of not less than 10 W/m·K (Watts per meter-Kelvin). A high-kappa material is particularly effective at conducting heat, and is also referred to as a thermal conductive material. This means the thermal vias 108 made of a high-kappa material allows heat to pass through them rapidly and efficiently. By way of example and not limitation, the thermal vias 108 may include a conductive material such as cobalt, titanium, tungsten, copper, aluminum, tantalum, titanium nitride, tantalum nitride, gold, silver, another metal, a metal alloy, or combinations thereof. Since the thermal vias 108 are not conducting electrical signals or power and thus not necessarily to be electrically conductive, the thermal vias 108 may include other high-kappa material, such as aluminum nitride (AlN), hexagonal boron nitride (h-BN), graphene, transition metal dichalcogenides (TMDs) (e.g., MoS₂, MoSc₂, WS₂ or WSe₂), or any other suitable high-kappa material. For aluminum nitride, it exhibits a high thermal conductivity of about 370 W/m·K. For graphene, it exhibits a high thermal conductivity above 3500 W/m·K. For TMDs, it generally exhibits a thermal conductivity above 10 W/m·K. For h-BN, it is in a layered structure in a crystalline form similar to graphite and exhibits an in-plane thermal conductivity above 390 W/m·K at room temperature. As a comparison, amorphous BN (a-BN) is in a non-crystalline amorphous form and only exhibits an in-plane thermal conductivity around 3 W/m·K, which is not considered as a high-kappa material in the context of the present disclosure. In one example, the dielectric layer 106 is formed of a-BN, while the thermal vias 108 are formed of h-BN.

In some embodiments, to further facilitate the heat dissipation, the dielectric layer 106 is also formed of a high-kappa dielectric material. In some embodiments, the dielectric layer 106 is a high-kappa dielectric layer having a thermal conductivity that is greater than a thermal conductivity of silicon dioxide but less than a thermal conductivity of the material of the thermal vias 108. In some embodiments, the bonding layer 104 is a high-kappa dielectric layer including one or more of a nitride, a metal oxide, or a carbide. In some embodiments, the bonding layer 104 includes one or more of AlN, BN, Y₂O₃, YAG, Al₂O₃, BeO, SiC, graphene, or any other suitable high-kappa material.

In various embodiments, the high-kappa materials of the dielectric layer 106 may be arranged in any suitable crystal structure, including, for example, cubic, hexagonal, tetragonal, orthorhombic, monoclinic, or triclinic. Moreover, the high-kappa materials of the dielectric layer 106 may have any suitable crystallinity, including, for example, monocrystal, polycrystal, or amorphous.

The use of the bonding structure 104, which has high-kappa materials in at least thermal vias 108 or both of the thermal vias 108 and the dielectric layer 106, facilitates improved thermal performance of the semiconductor device 100, for example, by preventing or reducing performance degradation of the semiconductor devices (e.g., within the semiconductor device layer 112) due to heat. The high-kappa materials used in the bonding structure 104 may improve heat dissipation, which may protect the semiconductor device layer 112 from heat degradation and which may therefore improve performance and reliability of the chip or semiconductor device 100.

Because the high-kappa bonding structure 104 is provided on the frontside of the semiconductor device 100 for heat dissipation, in some embodiments, there is no need to have external electrical contacts on the frontside of the semiconductor device 100 to transmit signals. As such, the frontside of the semiconductor device 100 may be free of electrical contacts, such as solder bumps, C4 connectors, or the like.

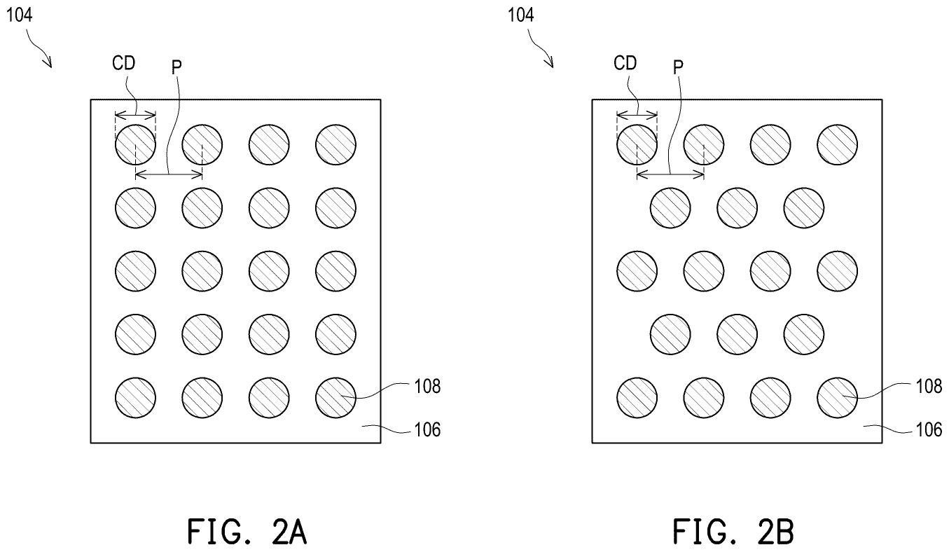

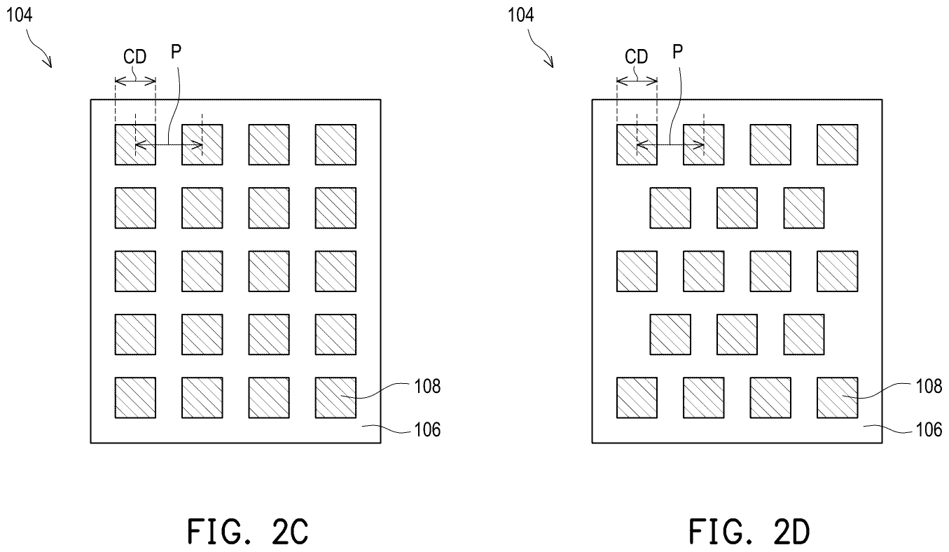

FIGS. 2A-2D illustrate some embodiments of the arrangement of the array of the thermal vias 108 in a top view of bonding structure 104. Each figure represents a different configuration of the thermal vias 108 within the bonding structure 104, offering options that vary in shape and spacing to cater to different thermal management needs in semiconductor applications. FIG. 2A illustrates an embodiment of an array consisting of circular thermal vias 108 embedded in the dielectric layer 106. The array is arranged in a uniform grid-like pattern with thermal vias arranged in rows and columns. FIG. 2B illustrates another embodiment of an array consisting of circular thermal vias 108 embedded in the dielectric layer 106. Unlike the uniform grid-like pattern in FIG. 2A, this array features an alternating arrangement, with each subsequent row of the thermal vias 108 shifted horizontally. This offset creates a staggered configuration. FIG. 2C illustrates the thermal vias 108 as squares (or rectangles) and are arranged in a dense, grid-like pattern similar to FIG. 2A. The square vias are tightly packed, providing a high via-to-area ratio, which may enhance the thermal transfer capabilities of the bonding structure 104. FIG. 2D illustrates another square thermal via configuration. Similar to FIG. 2B, the array in FIG. 2D features an alternating arrangement, with each subsequent row of the thermal vias 108 shifted horizontally. This offset creates a staggered configuration. In each of the illustrated embodiments, the thermal vias 108 may have a critical dimension (CD) ranging from about 1 μm to about 3 μm and a center-to-center distance (or referred to as a pitch) P ranging from about 1 μm to about 10 μm.

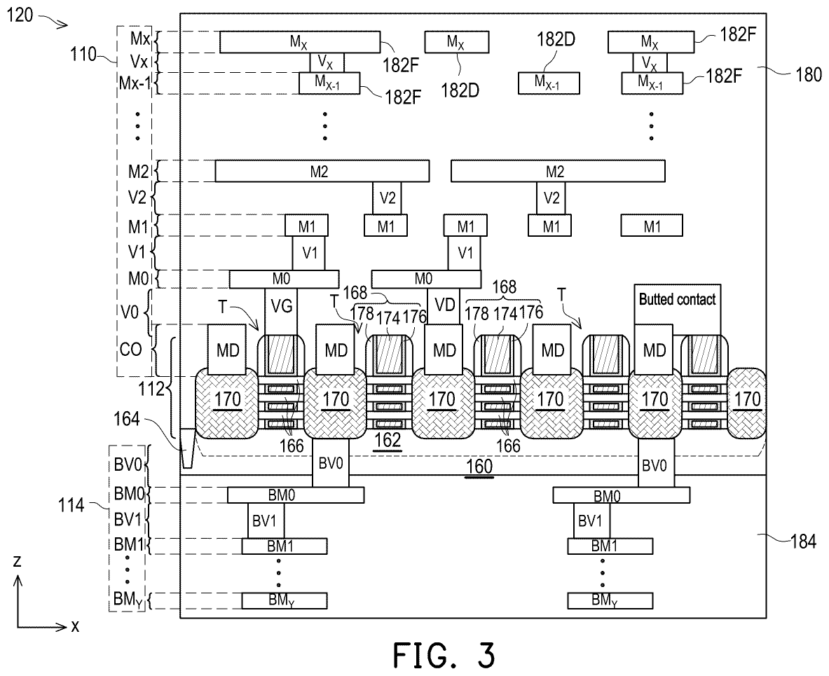

FIG. 3 is a detailed cross-sectional view of a region 120 of the semiconductor device 100 of FIG. 1, in accordance with some embodiments. As represented in FIG. 3, the various layers in the region 120 include the semiconductor device layer 112, the frontside interconnect structure 110 disposed over the semiconductor device layer 112, and the backside interconnect structure 114 disposed under the semiconductor device layer 112. FIG. 3 has been simplified for the sake of clarity to better understand the inventive concepts of the present disclosure. Additional features can be added in the various layers of the semiconductor device 100, and some of the features described can be replaced, modified, or eliminated in other embodiments of the semiconductor device 100.

The semiconductor device layer 112 includes devices (e.g., transistors, resistors, capacitors, and/or inductors) and/or device components (e.g., doped wells, gate structures, and/or source/drain features). In embodiments represented by FIG. 2, the semiconductor device layer 112 includes a substrate 160, doped regions 162 (e.g., n-wells and/or p-wells) disposed in the substrate 160, isolation feature 164, and transistors T. In the depicted embodiment, transistors T include suspended channel layers (nanostructures) 166 and gate structures 168 disposed between source/drain epitaxial features 170, where gate structures 198 wrap and/or surround suspended channel layers 166. Each gate structure 168 has a metal gate stack formed from a gate electrode 174 disposed over a gate dielectric layer 176 and gate spacers 178 disposed along sidewalls of the metal gate stack.

The interconnect structures 110 and 114 electrically couple various devices and/or components of the semiconductor device layer 112, such that the various devices and/or components can operate as specified by design requirements for the memory device. Each of the interconnect structures 110 and 114 may include one or more interconnect layers. In the depicted embodiment, the frontside interconnect structure 110 includes a contact interconnect layer (CO level), a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), and so on, up to the metal X-1 interconnect layer (M_{X-1} level), a via X-1 interconnect layer (V_{X-1} level), and a metal X interconnect layer (M_{X}) layer as the metal top layer. In some embodiments, X as an integer ranging from 1 to 10. Each of the CO level, V0 level, M0 level, V1 level, M1 level, V2 Level, M2 level, . . . M_{X} level may be referred to as a metal level. Metal lines formed at the M0 level may be referred to as M0 metal lines. Similarly, via or metal lines formed at the V1 level, M1 level, V2 level, M2 level . . . M_{X-1} level, V_{X-1} level, and M_{X} level may be referred to as V1 vias, M1 metal lines, V2 vias, M2 metal lines . . . M_{X-1} metal lines, V_{X-1} vias, and M_{X} metal lines, respectively. Each level of the frontside interconnect structure 110 includes conductive features (e.g., metal lines, metal vias, and/or metal contacts) disposed in one or more dielectric layers (e.g., an interlayer dielectric (ILD) layer or an inter-metal dielectric (IMD) layer). The dielectric layers of the frontside interconnect structure 110 are collectively referred to as a dielectric structure 180. In some embodiments, conductive features at a same level of the frontside interconnect structure 110, such as M0 level, are formed simultaneously. In some embodiments, conductive features at a same level of the frontside interconnect structure 110 have top surfaces that are substantially planar with one another and/or bottom surfaces that are substantially planar with one another.

In embodiments represented by FIG. 3, the CO level includes source/drain contacts MD disposed in the dielectric structure 180. The source/drain contacts MD may be formed on and in direct contact with silicide layers disposed directly on the source/drain epitaxial features 170. The V0 level includes gate vias VG disposed on the gate structures and source/drain contact vias VD disposed on the source/drain contacts MD, where gate vias VG connect gate structures to M0 metal lines, source/drain contact vias VD connect source/drain contacts MD to M0 metal lines. In some embodiments, the V0 level may also include butted contacts disposed in the dielectric structure 180. The V1 level includes V1 vias disposed in the dielectric structure 180, where V1 vias connect M0 metal lines to M1 metal lines. M1 level includes M1 metal lines disposed in the dielectric structure 180. V2 level includes V2 vias disposed in the dielectric structure 180, where V2 vias connect M1 metal lines to M2 metal lines. M2 level includes M2 metal lines disposed in the dielectric structure 180. Similarly, V_{X} level includes V_{X} vias disposed in the dielectric structure 180, where V_{X} vias connect M_{X-1} metal lines to M_{X} metal lines. Not all the metal lines in the frontside interconnect structure 110 are functional metal lines (denoted as metal lines 182F) that are configured to carry electric signals and/or power. The frontside interconnect structure 110 may also include non-functional metal lines (denoted as metal lines 182D) that are configured as dummy metal lines. Dummy metal lines are electrically floating. In a semiconductor structure, dummy metal lines help maintaining a uniform surface topography during a chemical-mechanical polishing (CMP) process, and also help in heat distribution across the chip, thereby avoiding hotspots which can affect the reliability and performance of the semiconductor device. FIG. 3 schematically illustrates that metal lines in the same metal interconnect layer may have both functional metal lines 182F and non-functional metal lines 182D. As to be discussed in further details below, in some embodiments, some of the thermal vias 108 (FIG. 1) may extend downwardly to land on some of the non-functional metal lines 182D. In furtherance of some embodiments, some of the thermal vias 108 may extend downwardly to land on the non-functional metal lines 182D in different metal interconnect layers (such as M_{X-1} level and M_{X} level), such that the bottom surfaces of different thermal vias 108 may be not level.

In the depicted embodiment, the backside interconnect structure 114 includes a backside via zero interconnect layer (BV0 level), a backside metal zero level (BM0 level), a backside via one interconnect layer (BV1 level), a backside metal one interconnect layer (BM1 level), and so on, down to the backside metal Y interconnect layer (BM_{Y} level). In some embodiments, Y as an integer ranging from 1 to 10. Each of the BV0 level, BM0 level, BV1 level, BM1, . . . and BM_{Y} level may be referred to as a metal level. Metal lines formed at the BM0 level may be referred to as BM0 metal lines. Similarly, via or metal lines formed at the BV0 level, BV1 level, BM1 level, . . . BM_{Y} level may be referred to as BV0 vias, BV1 vias, BM1 metal lines, . . . and BM_{Y} metal lines respectively. Each level of the backside interconnect structure 114 includes conductive features (e.g., metal lines, metal vias, and/or metal contacts) disposed in one or more dielectric layers (e.g., an ILD layer or an IMD layer). The dielectric layers of the backside interconnect structure 114 are collectively referred to as a backside dielectric structure 184. In some embodiments, conductive features at a same level of the backside interconnect structure 114, such as BM0 level, are formed simultaneously. In some embodiments, conductive features at a same level of the backside interconnect structure 114 have top surfaces that are substantially planar with one another and/or bottom surfaces that are substantially planar with one another. In embodiments represented by FIG. 3, the BV0 level includes vias BV0 formed under the semiconductor device layer 112. For example, the vias BV0 may include one or more backside source/drain vias formed directly under the source/drain epitaxial features 170 of the semiconductor device layer 112 and coupled to those source/drain epitaxial features 170 by way of a silicide layer. The BM0 level includes BM0 metal lines formed under the BV0 level. The backside source/drain vias connect source/drain epitaxial features 170 to BM0 metal lines. The BV1 level includes BV1 vias disposed in the backside dielectric structure 184, where BV1 vias connect BM0 metal lines to BM1 metal lines. The BM1 level includes BM1 metal lines formed under the BV1 level. Similarly, BV_{Y-1} level includes BV_{Y-1} vias disposed in the backside dielectric structure 184, where BV_{Y-1} vias connect BM_{Y-1} metal lines to BM_{Y} metal lines. Although not illustrated in FIG. 3, the BM_{Y} metal lines are further coupled to the electrical contacts 116 (FIG. 1) at the backside of the semiconductor device 100.

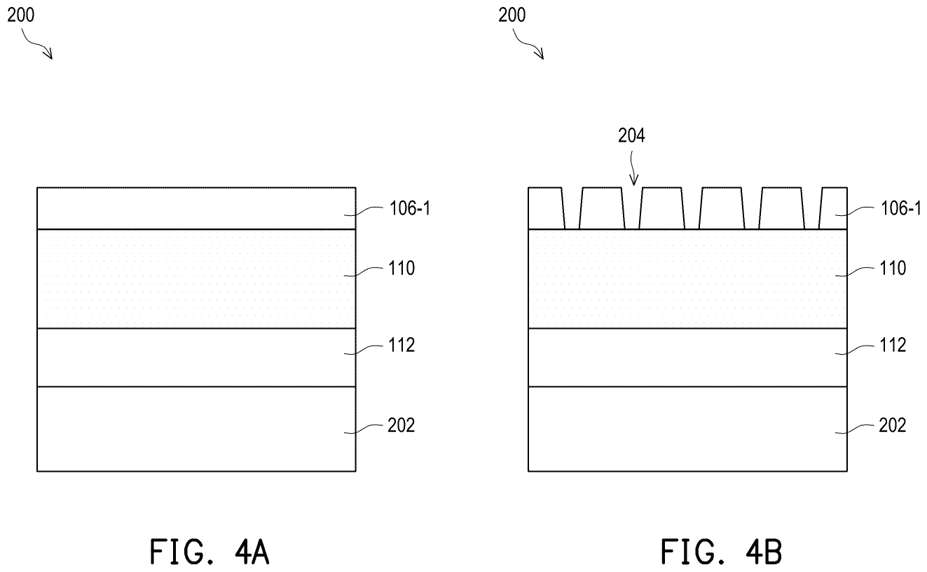

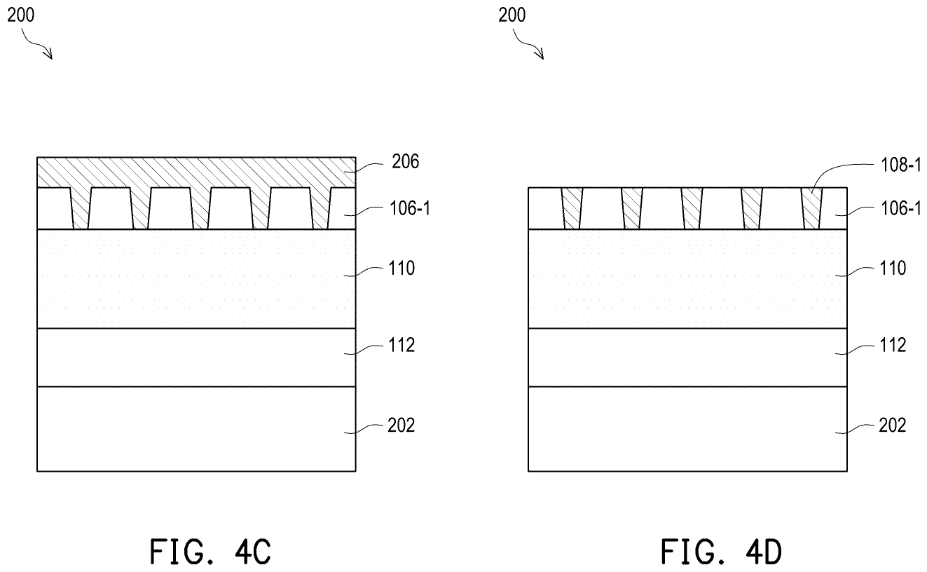

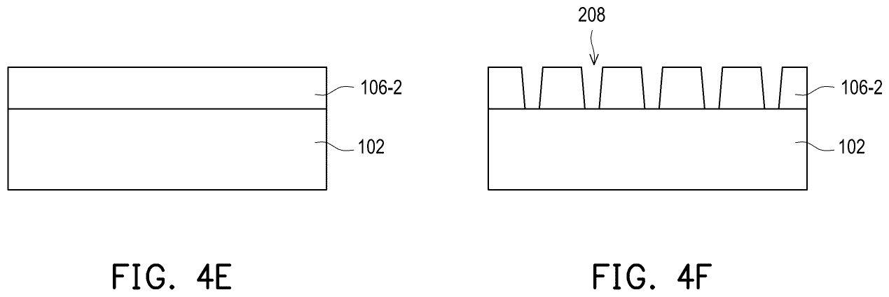

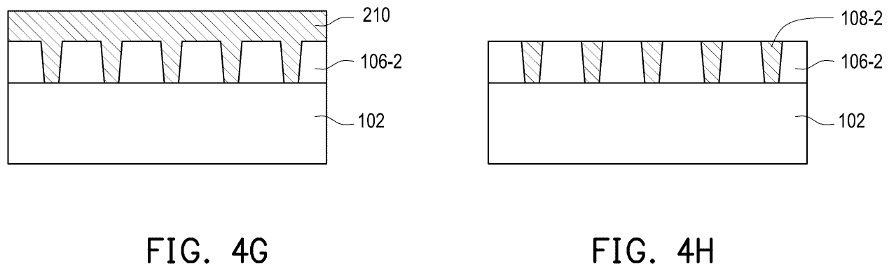

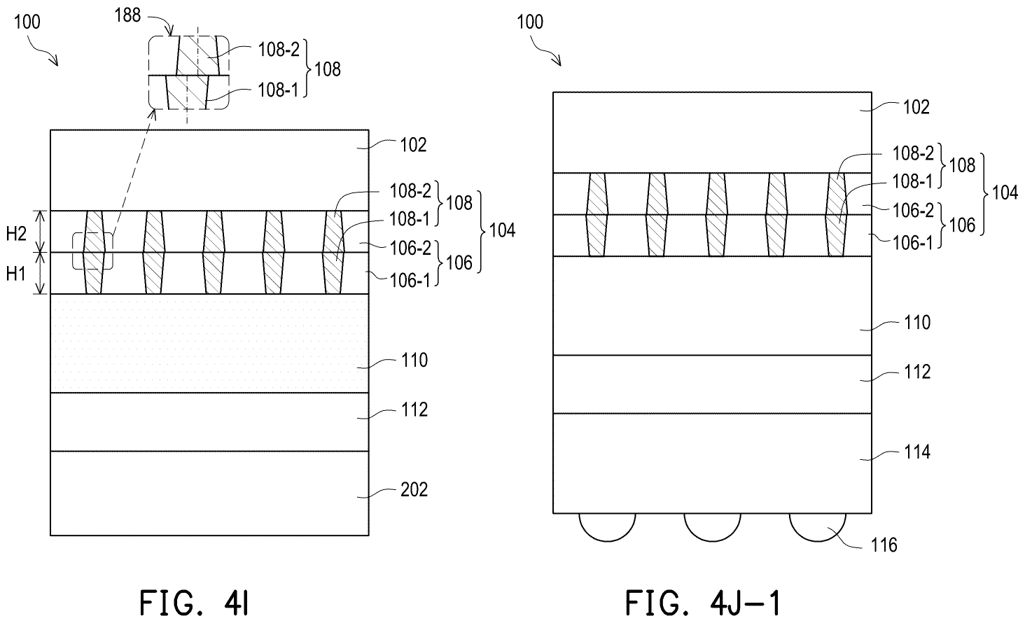

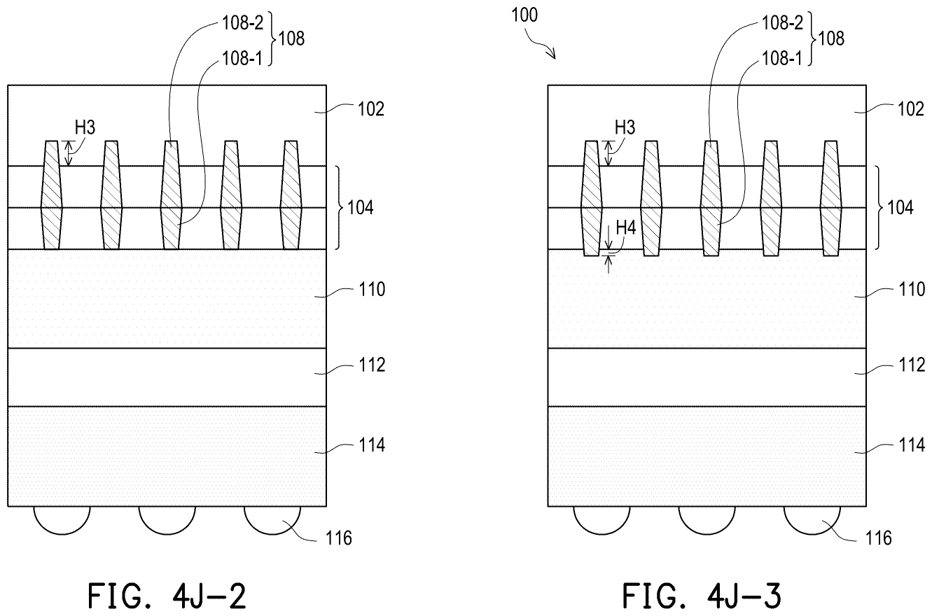

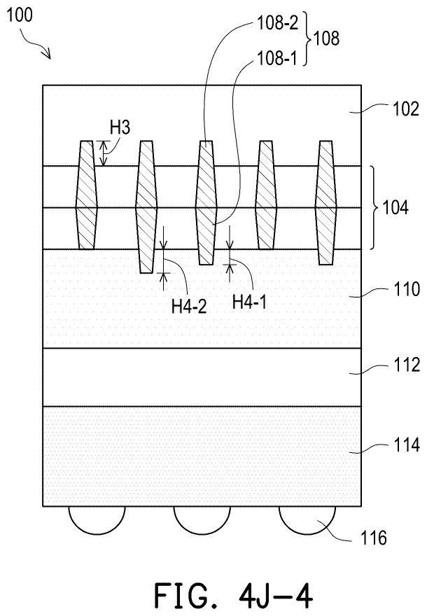

FIGS. 4A through 4J-1 illustrate a method of fabricating the semiconductor device 100, in accordance with some embodiments. As shown in FIG. 4A, the method includes forming a first dielectric layer 106-1 on a semiconductor device structure, which may be referred to as a device wafer 200. The device wafer 200 includes the semiconductor device layer 112 and the frontside interconnect structure 110, which may be the same or substantially the same as previously described herein.

The device wafer 200 further includes a substrate 202. The substrate 202 may be any suitable substrate. In some embodiments, the substrate 202 is a semiconductor substrate, such as a silicon substrate. The substrate 202 may be a semiconductor substrate, such as a bulk semiconductor, or the like, which may be doped (e.g., with a p-type or an n-type dopant) or undoped. The semiconductor material of the substrate 202 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used. The semiconductor device layer 112 may be formed on and/or in the substrate 202. The frontside interconnect structure 110 is formed on the semiconductor device layer 112, and may be the structure shown in FIG. 3 and described with reference thereto.

The first dielectric layer 106-1 may form a first portion or first sub-layer of the dielectric layer 106 of the bonding structure 104 of the semiconductor device 100. The first dielectric layer 106-1 may be formed by any suitable technique. For example, in some embodiments, the first dielectric layer 106-1 is formed by deposition of a non-high-kappa dielectric material or a high-kappa dielectric material. In some embodiments, the first dielectric layer 106-1 is a dielectric layer that is deposited by physical vapor deposition (PVD), chemical vapor deposition (CVD), atomic layer deposition (ALD), plasma enhanced CVD (PECVD), or any suitable deposition technique. In some embodiments, the first dielectric layer 106-1 has a thickness that is about half of the overall thickness of the dielectric layer 106 of the bonding structure 104, such as between about 0.5 um and about 5 um. In some other embodiments, the first dielectric layer 106-1 may have a thickness that is less than about half or more than about half of the overall thickness of the dielectric layer 106 of the bonding structure 104. The exact thickness of the first dielectric layer 106-1 is to facilitate suitable bonding between adjacent structures (e.g., bonding to a second dielectric layer 106-2 to be discussed in further details below).

As shown in FIG. 4B, the method includes forming a plurality of via trenches 204 in the first dielectric layer 106-1. The via trenches 204 extend through the first dielectric layer 106-1 and expose a portion of the top surface of the frontside interconnect structure 110. In some embodiments, forming the via trenches 204 includes forming a patterned mask layer (not shown) having openings therein that exposes a portion of the top surface of the first dielectric layer 106-1, and etching the first dielectric layer 106-1 using the patterned mask layer as an etch mask. The patterned mask layer may be formed using a lithography process, which can include resist coating (for example, spin-on coating), soft baking, mask aligning, exposure, post-exposure baking, developing the resist, rinsing, drying (for example, hard baking), other suitable process, or combinations thereof. In some embodiments, the patterned mask layer is a patterned hard mask layer (e.g., a silicon nitride layer). In some embodiments, the patterned mask layer is a patterned resist layer. The etching may be a dry etching process, a wet etching process, other etching process, or combinations thereof. In some embodiments, the etching process is an isotropic dry etch. Duc to loading effect of the etching process, the via trenches 204 may have tapered sidewalls such that the top opening of the via trenches 204 is larger than the bottom opening of the via trenches 204. After the forming of the via trenches 204, the patterned mask layer may be removed by an acceptable ashing or stripping process, such as using an oxygen plasma or the like.

As shown in FIG. 4C, the method includes depositing a high-kappa material 206 to fill the via trenches 204 and on the top surface of the first dielectric layer 106-1. The high-kappa material 206 may be a conductive material such as cobalt, titanium, tungsten, copper, aluminum, tantalum, titanium nitride, tantalum nitride, gold, silver, another metal, a metal alloy, or combinations thereof. Alternatively, the high-kappa material 206 may include non-conductive high-kappa material, such as aluminum nitride (AlN), hexagonal boron nitride (h-BN), graphene, transition metal dichalcogenides (TMDs) (e.g., MoS₂, MoSe₂, WS₂ or WSe₂), or any other suitable high-kappa material. In some embodiments, a liner (not shown) is conformally deposited on the device wafer 200 prior to the deposition of the bulk high-kappa material 206 that fills the remainder of the via trenches 204. The liner functions as a barrier that separates the high-kappa material 206 from direct contacting the first dielectric layer 106-1 and the dielectric structure 180 (FIG. 3) in the frontside interconnect structure 110. Therefore, the liner is also referred to as a barrier layer. The barrier layer blocks the material (e.g., copper) in the high-kappa material 206 from diffusing into the first dielectric layer 106-1 and the dielectric structure 180 in the frontside interconnect structure 110. In some embodiments, the barrier layer may be made of TiN or TaN.

As shown in FIG. 4D, the method includes performing a planarization process such as a Chemical Mechanical Planarization (CMP) process or a mechanical polish process to remove excess portions of the high-kappa material 206, hence forming thermal vias in the first dielectric layer 106-1. The thermal vias formed in the first dielectric layer 106-1 are denoted as first thermal vias 108-1. The first thermal vias 108-1 inherit the shape of the via trenches 204. Due to the larger top opening and smaller bottom opening of the via trenches 204, the first thermal vias 108-1 have tapered sidewalls and larger top width and smaller bottom width. In the illustrated embodiment, the top surface of the first dielectric layer 106-1 is exposed.

As shown in FIG. 4E, the method includes forming a second dielectric layer 106-2 on the carrier substrate 102, such as a semiconductor wafer. In some embodiments, the carrier substrate 102 may be a monocrystalline silicon (Si) wafer, an amorphous Si wafer, a gallium arsenide (GaAs) wafer, or any other semiconductor wafer. The second dielectric layer 106-2 may form a second portion or second sub-layer of the dielectric layer 106 of the bonding structure 104 of the semiconductor device 100. The second dielectric layer 106-2 may be formed by any suitable technique. For example, in some embodiments, the second dielectric layer 106-2 is formed by deposition of a non-high-kappa dielectric material or a high-kappa dielectric material. In some embodiments, the second dielectric layer 106-2 is a dielectric layer that is deposited by physical vapor deposition (PVD), chemical vapor deposition (CVD), atomic layer deposition (ALD), plasma enhanced CVD (PECVD), or any suitable deposition technique. In some embodiments, the material compositions in the first dielectric layer 106-1 and the second dielectric layer 106-2 are the same. Alternatively, the material compositions in the first dielectric layer 106-1 and the second dielectric layer 106-2 may be different for some specific application needs. In some embodiments, the second dielectric layer 106-2 has a thickness that is about half of the overall thickness of the dielectric layer 106 of the bonding structure 104, such as between about 0.5 um and about 5 um. In some other embodiments, the second dielectric layer 106-2 may have a thickness that is larger than the thickness of the first dielectric layer 106-1 or smaller than the thickness of the first dielectric layer 106-1. The exact thickness of the second dielectric layer 106-2 is to facilitate suitable bonding between the first dielectric layer 106-1 and the second dielectric layer 106-2.

As shown in FIG. 4F, the method includes forming a plurality of via trenches 208 in the second dielectric layer 106-2. The via trenches 208 extend through the second dielectric layer 106-2 and expose a portion of the top surface of the carrier substrate 102. In some embodiments, forming the via trenches 208 includes forming a patterned mask layer (not shown) having openings therein that exposes a portion of the top surface of the second dielectric layer 106-2, and etching the second dielectric layer 106-2 using the patterned mask layer as an etch mask. The patterned mask layer may be formed using a lithography process, which can include resist coating (for example, spin-on coating), soft baking, mask aligning, exposure, post-exposure baking, developing the resist, rinsing, drying (for example, hard baking), other suitable process, or combinations thereof. In some embodiments, the patterned mask layer is a patterned hard mask layer (e.g., a silicon nitride layer). In some embodiments, the patterned mask layer is a patterned resist layer. The etching may be a dry etching process, a wet etching process, other etching process, or combinations thereof. In some embodiments, the etching process is an isotropic dry etch. Due to loading effect of the etching process, the via trenches 208 may have tapered sidewalls such that the top opening of the via trenches 208 is larger than the bottom opening of the via trenches 208. After the forming of the via trenches 208, the patterned mask layer may be removed by an acceptable ashing or stripping process, such as using an oxygen plasma or the like.

As shown in FIG. 4G, the method includes depositing a high-kappa material 210 to fill the via trenches 208 and on the top surface of the second dielectric layer 106-2. The high-kappa material 210 may be a conductive material such as cobalt, titanium, tungsten, copper, aluminum, tantalum, titanium nitride, tantalum nitride, gold, silver, another metal, a metal alloy, or combinations thereof. Alternatively, the high-kappa material 210 may include non-conductive high-kappa material, such as aluminum nitride (AlN), hexagonal boron nitride (h-BN), graphene, transition metal dichalcogenides (TMDs) (e.g., MoS₂, MoSe₂, WS₂ or WSe₂), or any other suitable high-kappa material. In some embodiments, a liner (not shown) is conformally deposited on the workpiece prior to the deposition of the bulk high-kappa material 210 that fills the remainder of the via trenches 208. The liner functions as a barrier that separates the high-kappa material 210 from direct contacting the second dielectric layer 106-2 and the carrier substrate 102. Therefore, the liner is also referred to as a barrier layer. The barrier layer blocks the material in the high-kappa material 210 from diffusing into the second dielectric layer 106-2 and the carrier substrate 102. In some embodiments, the barrier layer may be made of TiN or TaN. In some embodiments, the material compositions in the high-kappa material 206 and the high-kappa material 210 are the same. Alternatively, the material compositions in the high-kappa material 206 and the high-kappa material 210 may be different for some specific application needs. For example, there is less concern for the diffusion of the material composition in the high-kappa material 210 into the carrier substrate 102, and thus there may be less restriction on the selection of the high-kappa material 210. In furtherance of some embodiments, since there is less concern for the diffusion of the material composition in the high-kappa material 210 into the carrier substrate 102, there is no barrier layer underneath the high-kappa material 210, while there is a barrier layer under the high-kappa material 206.

As shown in FIG. 4H, the method includes performing a planarization process such as a Chemical Mechanical Planarization (CMP) process or a mechanical polish process to remove excess portions of the high-kappa material 210, hence forming thermal vias in the second dielectric layer 106-2. The thermal vias formed in the second dielectric layer 106-2 are denoted as second thermal vias 108-2. The second thermal vias 108-2 inherit the shape of the via trenches 208. Duc to the larger top opening and smaller bottom opening of the via trenches 208, the second thermal vias 108-2 have tapered sidewalls and larger top width and smaller bottom width. In the illustrated embodiment, the top surface of the second dielectric layer 106-2 is exposed.

As shown in FIG. 4I, the carrier substrate 102 is bonded to the device wafer 200 to form the semiconductor device 100. The carrier substrate 102 protects the frontside interconnect structure 110 during backside processing of the device wafer 200. The device wafer 200 and carrier substrate 102 may be bonded to one another by any suitable technique. In some embodiments, the carrier substrate 102 is bonded to the device wafer 200 by an ambient bonding process, for example, with ambient temperature or pressure process parameters in a bonding tool. In some embodiments, the carrier substrate 102 is bonded to the device wafer 200 by a vacuum bonding process, for example, in a bonding tool with vacuum pressure. However, embodiments are not limited thereto, and in various embodiments, bonding of the carrier substrate 102 to the device wafer 200 may be performed by any suitable bonding process. During the bonding process, the second dielectric layer 106-2 on the carrier substrate 102 are bonded to the first dielectric layer 106-1 formed on the device wafer 200, and the second thermal vias 108-2 formed in the second dielectric layer 106-2 are bonded to the first thermal vias 108-1 formed in the first dielectric layer 106-1. Since the bonding interfaces between the dielectric layers and thermal vias are different, the bonding process is also referred to as a hybrid bonding process.

After the bonding process, the first dielectric layer 106-1 and the second dielectric layer 106-2 collectively form the dielectric layer 106, a pair of the first thermal vias 108-1 and the second thermal via 108-2 collectively form one thermal via 108, and the dielectric layer 106 and the array of the thermal vias 108 collectively form the bonding structure 104. As discussed above, a thickness H1 of the first dielectric layer 106-1 (or a height of the first thermal via 108-1) may be equal to a thickness H2 of the second dielectric layer 106-2 (or a height of the second thermal via 108-2). Alternatively, the thickness H1 may be larger or smaller than the thickness H2 depending on specific performance needs. Generally, centerlines of the first thermal via 108-1 and the second thermal via 108-2 in a respective pair are aligned during the bonding process. Due to the taper sidewalls of the first thermal vias 108-1 and the second thermal vias 108-2, the thermal vias 108 each have a middle portion that is wider than the top and bottom portions. If bonding overlaying shift occurs, the centerlines of the first thermal via 108-1 and the second thermal via 108-2 in a respective pair may be horizontally offset and creates step profiles along the sidewalls of the thermal via 108, which is illustrated in an enlarged area 188 as shown in FIG. 4I.

As shown in FIG. 4J-1, the semiconductor device 100 is further formed by forming the backside interconnection structure 114 at the backside of the semiconductor device layer 112. The backside interconnection structure 114 may be the same as or similar to that described with reference to FIG. 3. In some embodiments, formation of the backside interconnection structure 114 includes forming a plurality of conductive features operable to deliver or receive electrical signals to or from semiconductor devices in the semiconductor device layer 112. For example, the backside interconnection structure 114 may include one or more backside power rails, metallization layers, conductive vias, and the like. In some embodiments, formation of the backside interconnection structure 114 includes forming an insulation layer on or around the conductive features of the backside interconnection structure 114. In some embodiments, one or more portions of the substrate 202 may be at least partially removed, for example, as part of the formation of the backside interconnection structure 114. In some embodiments, the backside interconnection structure 114 is formed in or at least partially includes portions of the substrate 202. For example, in some embodiments, the conductive features of the backside interconnection structure 114 (e.g., backside power rails, metallization layers, conductive vias, or the like) may be formed within the substrate 202. The conductive features of the backside interconnection structure 114 may be formed to extend through the substrate 202 or insulation layer and may contact conductive or semiconductor regions (e.g., gate contact of a transistor, source/drain regions of a transistor, etc.) of the semiconductor devices in the semiconductor device layer 112.

Further, as shown in FIG. 4J-1, the semiconductor device 100 is further formed by forming the electrical contacts 116. The electrical contacts 116 may be formed by any suitable technique, including by deposition, soldering, placement of solder balls, or the like. The electrical contacts 116 may be formed on or in contact with a metallization layer of the backside interconnection structure 114, which may include power contacts, input/output contacts or any other contacts for receiving or providing electrical signals and/or power. In various embodiments, any number of electrical contacts may be included in the semiconductor device 100 and may be coupled to various different conductive features or metallization pathways, e.g., to electrically couple to the semiconductor devices in the semiconductor device layer 112.

In the embodiment as illustrated in FIG. 4J-1, the thermal vias 108 each extend from a top surface of the frontside interconnect structure 110 to a surface of the carrier substrate 102 facing the frontside interconnect structure 110, facilitating heat dissipation from the semiconductor device layer 112 and the frontside interconnect structure 110 into the carrier substrate 102. FIGS. 4J-2, 4J-3, and 4J-4 illustrate some alternative embodiments of the thermal vias 108 in the semiconductor device 100. As shown in FIG. 4J-2, the second thermal vias 108-2 each further extends upwardly into the carrier substrate 102, which is formed by extending the via trenches 208 into the carrier substrate 102 during the etching process (FIG. 4F). By partially embedding the second thermal vias 108-2 in the carrier substrate 102, contacting area between the second thermal vias 108-2 and the carrier substrate 102 is enlarged, allowing heat to be dissipated into the carrier substrate 102 more effectively. With the extra portion extending into the carrier substrate 102, the second thermal vias 108-2 may have a larger height than the first thermal vias 108-1. The portion extended in the carrier substrate 102 may have a height H3 that is about 10% to about 30% of a total height of the thermal via 108.

As shown in FIG. 4J-3, the first thermal vias 108-1 each further extend downwardly into the frontside interconnect structure 110, which is formed by extending the via trenches 204 into the dielectric structure 180 (FIG. 3) of the frontside interconnect structure 110 during the etching process (FIG. 4B). By partially embedding the first thermal vias 108-1 in the frontside interconnect structure 110, contacting area between the first thermal vias 108-1 and the frontside interconnect structure 110 is enlarged, allowing heat to be dissipated away from the semiconductor device layer 112 and the frontside interconnect structure 110 more effectively. The portion extended in the frontside interconnect structure 110 may have a height H4 that is about 10% to about 30% of a total height of the thermal via 108. In various embodiments, the height H4 may be equal to, smaller than, or larger than the height H3 depending on specific application needs.

As shown in FIG. 4J-4, some of the first thermal vias 108-1 positioned directly above the non-functional metal lines 182D (FIG. 3) in the frontside interconnect structure 110 may extend downwardly to have direct contact with respective non-functional metal lines 182D underneath, which is formed by extending the via trenches 204 into the dielectric layer of the frontside interconnect structure 110 during the etching process (FIG. 4B). Direct contact between the non-functional metal lines 182D and the first thermal vias 108-1 allows heat to be dissipated away from the semiconductor device layer 112 and the frontside interconnect structure 110 more effectively. Depending on the depth of the non-functional metal lines 182D (e.g., as shown in FIG. 3, top non-functional metal lines 182D may be in M_{X} and/or M_{X-1} metal layers), some of the first thermal vias 108-1 may extend deeper into the frontside interconnect structure 110 than some other first thermal vias 108-2 (e.g., H4-2>H4-1). Also, some of the first thermal vias 108-1 positioned directly above the functional metal lines 182F (FIG. 3) in the frontside interconnect structure 110 may land on the top surface of the frontside interconnect structure 110 without extending thereinto. Thus, the bottom surfaces of the thermal vias 108 may be non-coplanar. As a comparison, the top surfaces of the thermal vias 108 are substantially coplanar.

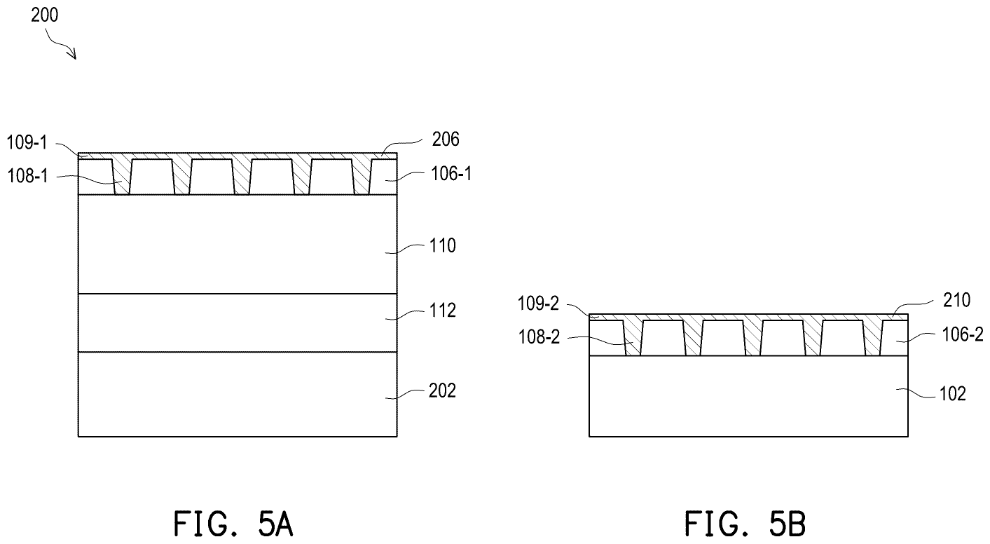

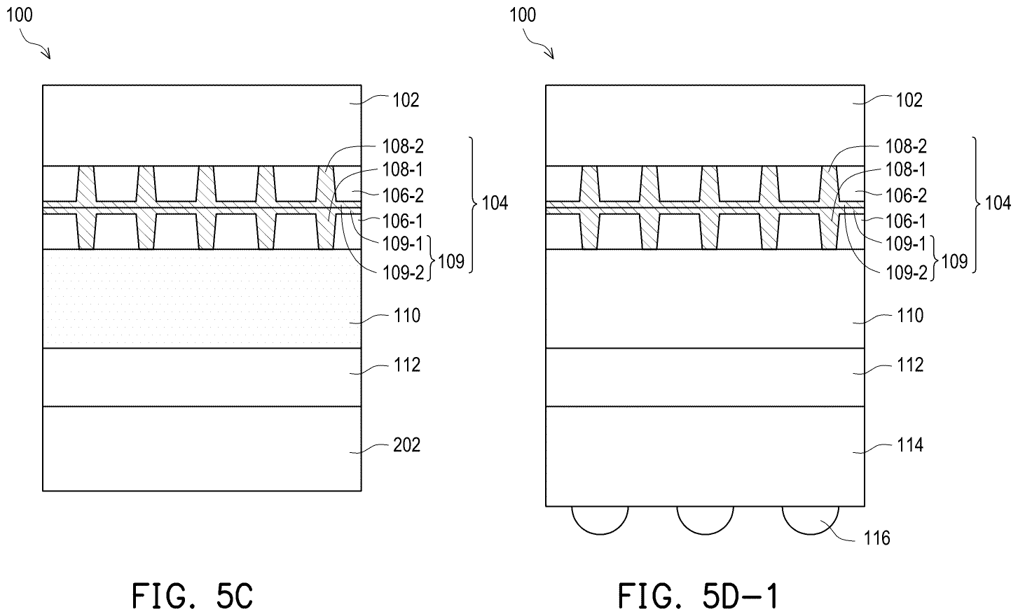

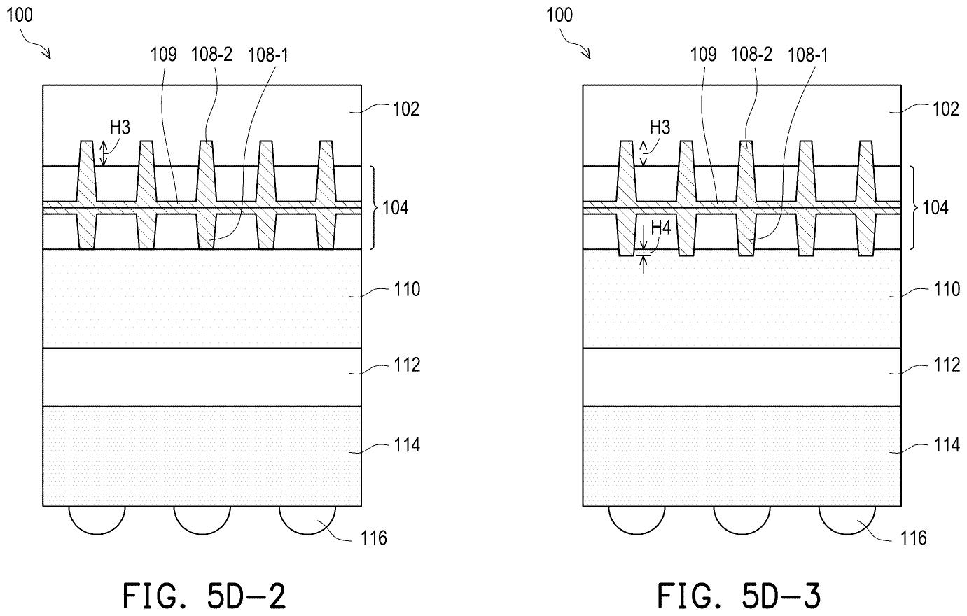

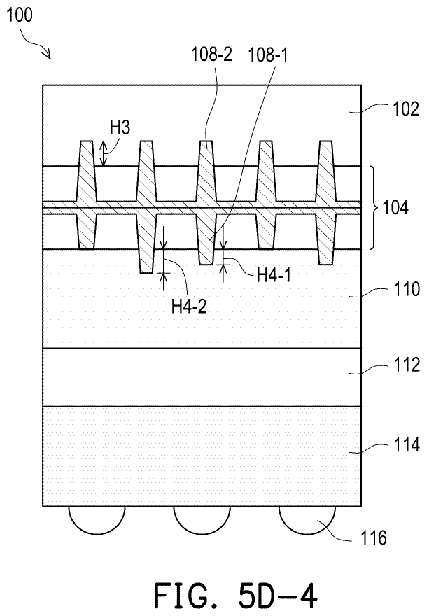

FIGS. 5A-5D-1 illustrate an alternative method of manufacturing the semiconductor device 100. Other than removing the excess portions of the high-kappa material 206 to expose the first dielectric layer 106-1 (FIG. 4D), in FIG. 5A, a thin layer of the high-kappa material 206 remains after the planarization process, covering the first dielectric layer 106-1. The thin layer is denoted as the first thermal sheet 109-1. Similarly, other than removing the excess portions of the high-kappa material 210 to expose the second dielectric layer 106-2 (FIG. 4H), in FIG. 5B, a thin layer of the high-kappa material 210 remains after the planarization process, covering the second dielectric layer 106-2. The thin layer is denoted as the second thermal sheet 109-2.

As shown in FIG. 5C, the carrier substrate 102 is bonded to the device wafer 200 to form the semiconductor device 100. The first thermal sheet 109-1 is bonded to the second thermal sheet 109-2, collectively forming a thermal sheet 109. The thermal sheet 109 interposes between the first dielectric layer 106-1 and the second dielectric layer 106-2 and separates the first dielectric layer 106-1 from direct contacting the second dielectric layer 106-2. The thermal sheet 109 provides larger thermal conductive interface than the bonded thermal vias, facilitating heat dissipation from the semiconductor device layer 112 and the frontside interconnect structure 110 into the carrier substrate 102.

As shown in FIG. 5D-1, the semiconductor device 100 is further formed by forming the backside interconnection structure 114 at the backside of the semiconductor device layer 112. The backside interconnection structure 114 may be the same as or similar to that described with reference to FIG. 3. The semiconductor device 100 is further formed by forming the electrical contacts 116. The electrical contacts 116 may be formed by any suitable technique, including by deposition, soldering, placement of solder balls.

FIGS. 5D-2, 5D-3, and 5D-4 are alternative embodiments similar to the ones depicted in FIGS. 4J-2, 4J-3, and 4J-4 but with the extra thermal sheet 109. As shown in FIG. 5D-2, the second thermal vias 108-2 each further extends upwardly into the carrier substrate 102, which is formed by extending the via trenches 208 into the carrier substrate 102 during the etching process (FIG. 4F). By partially embedding the second thermal vias 108-2 in the carrier substrate 102, contacting area between the second thermal vias 108-2 and the carrier substrate 102 is enlarged, allowing heat to be dissipated into the carrier substrate 102 more effectively. With the extra portion extending into the carrier substrate 102, the second thermal vias 108-2 may have a larger height than the first thermal vias 108-1. The portion extended in the carrier substrate 102 may have a height H3 that is about 10% to about 30% of a total height of the first thermal via 108-1 and the second thermal via 108-2.

As shown in FIG. 5D-3, the first thermal vias 108-1 each further extend downwardly into the frontside interconnect structure 110, which is formed by extending the via trenches 204 into the dielectric layer of the frontside interconnect structure 110 during the etching process (FIG. 4B). By partially embedding the first thermal vias 108-1 in the frontside interconnect structure 110, contacting area between the first thermal vias 108-1 and the frontside interconnect structure 110 is enlarged, allowing heat to be dissipated away from the semiconductor device layer 112 and the frontside interconnect structure 110 more effectively. The portion extended in the frontside interconnect structure 110 may have a height H4 that is about 10% to about 30% of a total height of the first thermal via 108-1 and the second thermal via 108-2. In various embodiments, the height H4 may be equal to, smaller than, or larger than the height H3 depending on specific application needs.

As shown in FIG. 5D-4, some of the first thermal vias 108-1 positioned directly above the non-functional metal lines 182D (FIG. 3) in the frontside interconnect structure 110 may extend downwardly to have direct contact with the respective non-functional metal lines 182D underneath, which is formed by extending the via trenches 204 into the dielectric layer of the frontside interconnect structure 110 during the etching process (FIG. 4B). Direct contact between the non-functional metal lines 182D and the first thermal vias 108-1 allows heat to be dissipated away from the semiconductor device layer 112 and the frontside interconnect structure 110 more effectively. Depending on the depth of the non-functional metal lines 182D (e.g., as shown in FIG. 3, top non-functional metal lines 182D may be in M_{X} and/or M_{X-1} metal layers), some of the first thermal vias 108-1 may extend deeper into the frontside interconnect structure 110 than some other first thermal vias 108-2 (e.g., H4-2>H4-1). Also, some of the first thermal vias 108-1 positioned directly above the functional metal liens 182F in the frontside interconnect structure 110 (FIG. 3) may land on the top surface of the frontside interconnect structure 110 without extending thereinto. Thus, the bottom surfaces of the first thermal vias 108-1 may be non-coplanar. As a comparison, the bottom surfaces (upside-down positioned) of the second thermal vias 108-2 are substantially coplanar.

The embodiments of the present disclosure have some advantageous features. By forming a bonding structure that provides thermal conductive vias, thermal performance of the semiconductor device is promoted, which prevents potential overheating and aids in prolonging the device's lifespan and maintaining the device's operational efficiency.

In one exemplary aspect, the present disclosure is directed to a method. The method includes forming a first dielectric layer on a semiconductor structure, the semiconductor structure including a semiconductor device layer having a frontside and a backside, a first substrate disposed on the backside of the semiconductor device layer, and a first interconnect structure disposed on the frontside of the semiconductor device layer, forming a plurality of first vias through the first dielectric layer and extending to the first interconnect structure, the first vias having a first thermal conductive material with a thermal conductivity greater than about 10 W/m·K, forming a second dielectric layer on a second substrate, forming a plurality of second vias through the second dielectric layer and extending to the second substrate, the second vias having a second thermal conductive material with a thermal conductivity greater than about 10 W/m·K, bonding the second dielectric layer to the first dielectric layer and the second vias to the first vias, and forming a second interconnect structure on the backside of the semiconductor device layer. In some embodiments, the forming of the second interconnect structure includes thinning or removing the first substrate. In some embodiments, the forming of the first vias includes patterning the first dielectric layer to form a plurality of first via trenches, depositing the first thermal conductive material in the first via trenches and over the first dielectric layer, and performing a first planarization process to partially remove the first thermal conductive material, such that portions of the first thermal conductive material remaining in the first via trenches form the first vias. In some embodiments, the forming of the second vias includes patterning the second dielectric layer to form a plurality of second via trenches, depositing the second thermal conductive material in the second via trenches and over the second dielectric layer, and performing a second planarization process to partially remove the second thermal conductive material, such that portions of the second thermal conductive material remaining in the second via trenches form the second vias. In some embodiments, the first and second thermal conductive materials are electric conductive materials. In some embodiments, the first and second thermal conductive materials are electric non-conductive materials. In some embodiments, the first and second thermal conductive materials have different material compositions. In some embodiments, the first and second dielectric layers are made of a dielectric material with a thermal conductivity greater than about 10 W/m·K. In some embodiments, the first and second dielectric layers are made of a dielectric material with a thermal conductivity less than about 10 W/m·K. In some embodiments, the second vias are partially embedded in the second substrate.

In another exemplary aspect, the present disclosure is directed to a method. The method includes forming a first interconnect structure on a first side of a semiconductor device layer, forming a bonding structure connecting the first interconnect structure and a substrate, the bonding structure including a dielectric layer and an array of thermal conductive pillars extending through the dielectric layer, the thermal conductive pillars being electrically isolated from the semiconductor device layer, and forming a second interconnect structure on a second side of the semiconductor device layer, the second side of the semiconductor device layer facing away from the first side of the semiconductor device layer. In some embodiments, the thermal conductive pillars each have a middle portion that is wider than a top portion and a bottom portion. In some embodiments, the thermal conducive pillars each have a cross section of a circular shape. In some embodiments, the thermal conducive pillars each have a cross section of a square shape. In some embodiments, the bonding structure further includes a thermal sheet dividing the dielectric layer into an upper portion in thermal coupling with the substrate and a lower portion in thermal coupling with the first interconnect structure. In some embodiments, the dielectric layer is made of a thermal conductive dielectric material with a thermal conductivity greater than about 10 W/m·K.

In yet another exemplary aspect, the present disclosure is directed to a semiconductor device. The semiconductor device includes a semiconductor device layer, a frontside interconnect structure over the semiconductor device layer, a backside interconnect structure under the semiconductor device layer, and a substrate bonded to the frontside interconnect structure through a bonding structure. The bonding structure includes a dielectric layer and a plurality of thermal pillars extending through the dielectric layer. The thermal pillars having first ends interfacing the frontside interconnect structure and second ends interfacing the substrate. In some embodiments, the thermal pillars are arranged in rows and columns in forming an array. In some embodiments, the bonding structure further includes a thermal sheet dividing the dielectric layer into an upper portion in thermal coupling with the substrate and a lower portion in thermal coupling with the frontside interconnect structure. In some embodiments, the thermal pillars each has a sidewall having a first tapered portion and a second taper portion that is tapered in an opposite direction with respect to the first tapered portion.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor device layer comprising a plurality of transistors;
a frontside interconnect structure disposed over the semiconductor device layer and electrically coupled to the transistors, the frontside interconnect structure comprising a plurality of interconnect layers, each of the interconnect layers comprising metal lines disposed in a dielectric layer;
a backside interconnect structure disposed under the semiconductor device layer and electrically coupled to the transistors;
a bonding structure disposed over the frontside interconnect structure; and
a carrier substrate disposed over the bonding structure,
wherein the bonding structure includes a plurality of thermal pillars embedded in a substrate, top surfaces of the thermal pillars interface with the carrier substrate, bottom surfaces of the thermal pillars interface with the frontside interconnect structure.

2. The semiconductor device of claim 1, wherein the thermal pillars have a thermal conductivity not less than 10 W/m·K.

3. The semiconductor device of claim 2, wherein the substrate of the bonding structure has a thermal conductivity less than 10 W/m·K.

4. The semiconductor device of claim 2, wherein the substrate of the bonding structure has a thermal conductivity not less than 10 W/m·K, but less than the thermal conductivity of the thermal pillars.

5. The semiconductor device of claim 1, wherein the thermal pillars are formed of hexagonal boron nitride.

6. The semiconductor device of claim 5, wherein the substrate of the bonding structure is formed of amorphous boron nitride.

7. The semiconductor device of claim 1, wherein the top surfaces of the thermal pillars are coplanar, and the bottom surfaces of the thermal pillars are non-coplanar.

8. The semiconductor device of claim 7, wherein the bottom surfaces of the thermal pillars interfaces with the metal lines in more than one interconnect layers.

9. The semiconductor device of claim 1, wherein a middle portion of the thermal pillars is wider than top and bottom portions of the thermal pillars.

10. The semiconductor device of claim 1, wherein the substrate of the bonding structure includes a top portion adjacent to the carrier substrate and a bottom portion adjacent to the frontside interconnect structure, each of the thermal pillars has a top part embedded in the top portion of the substrate and a bottom part embedded in the bottom portion of the substrate, and the top part and the bottom part of the thermal pillars include different material compositions.

11. A semiconductor device, comprising:
a semiconductor device layer;
a frontside interconnect structure over the semiconductor device layer;
a backside interconnect structure under the semiconductor device layer;
solder bumps disposed under the backside interconnect structure; and
a substrate bonded to the frontside interconnect structure through a bonding structure,
wherein the bonding structure includes:
a dielectric layer; and
a plurality of thermal pillars arranged in rows and columns of an array and extending through the dielectric layer, the thermal pillars having bottom surfaces interfacing with the frontside interconnect structure and top surfaces interfacing with the substrate.

12. The semiconductor device of claim 11, wherein the top surfaces of the thermal pillars are embedded in the substrate.

13. The semiconductor device of claim 11, wherein the bottom surfaces of the thermal pillars are embedded in the frontside interconnect structure.

14. The semiconductor device of claim 11, wherein the bonding structure further includes:
a thermal sheet dividing the dielectric layer into an upper portion in thermal coupling with the substrate and a lower portion in thermal coupling with the frontside interconnect structure.

15. The semiconductor device of claim 11, wherein the thermal pillars each has a sidewall having a first tapered portion and a second taper portion that is tapered in an opposite direction with respect to the first tapered portion.

16. The semiconductor device of claim 11, wherein the dielectric layer and the thermal pillars are both made of high-kappa materials, a thermal conductivity of the thermal pillars is greater than a thermal conductivity of the dielectric layer.

17. A method, comprising:
forming a semiconductor device layer comprising a plurality of transistors;
forming a frontside interconnect structure on a frontside of the semiconductor device layer and in electrical coupling with the transistors;
forming a bonding structure connecting the frontside interconnect structure and a carrier substrate, the bonding structure including a dielectric layer and an array of thermal conductive pillars extending through the dielectric layer, the thermal conductive pillars being electrically isolated from the transistors; and
forming a backside interconnect structure on a backside of the semiconductor device layer and in electrical coupling with the transistors.

18. The method of claim 17, wherein the thermal conductive pillars each have a middle portion that is wider than a top portion and a bottom portion.

19. The method of claim 17, wherein the bonding structure further includes:
a thermal sheet dividing the dielectric layer into an upper portion in thermal coupling with the carrier substrate and a lower portion in thermal coupling with the frontside interconnect structure.

20. The method of claim 17, wherein the dielectric layer is made of a thermal conductive dielectric material with a thermal conductivity greater than about 10 W/m·K.
